(19) United States
(12) Patent Application Publication
(10) Pub. No.: US 2007/0066002 A1
(43) Pub. Date: Mar. 22, 2007

(54) Source capacitor enhancement for improved dynamic IR drop prevention

(76) Inventors: Peter J. Hopper, San Jose, CA (US); Philipp Lindorfer, San Jose, CA (US); Vladislav Vashchenko, Palo Alto, CA (US); Yuri Mirgorodski, Sunnyvale, CA (US)

Correspondence Address: STALLMAN & POLLOCK LLP, 353 SACRAMENTO STREET, SUITE 2200, SAN FRANCISCO, CA, 94111, US

(21) Appl. No.: 11/601,485

(22) Filed: Nov. 17, 2006

Related U.S. Application Data
(62) Division of application No. 10/833,212, filed on Apr. 27, 2004.

(51) Int. Cl. H01L 21/8238

(52) U.S. Cl. 438/199

(57) ABSTRACT

An implant is added at the interface between the source region of an MOS transistor and the well material to improve dynamic IR drop performance. The additional implant raises the underlying capacitance of the source region. This, in turn, provides for an increase in charge storage which, in turn, provides for an improved level of protection against dynamic IR drop.

### RELATED APPLICATION

This is a divisional application of co-pending and commonly assigned application Ser. No. 10/833,212, filed on Apr. 27, 2004, and which is hereby incorporated by reference in its entirety.

### FIELD OF THE INVENTION

The present invention is directed to a technique for raising the source capacitance of MOS transistors in an integrated circuit by implanting dopant at the source/well interface.

### BRIEF DESCRIPTION OF THE DRAWINGS

FIG. 1 is a partial cross-section drawing illustrating an N+ implant to raise the capacitance of the source region in a PMOS device in accordance with the concepts of the present invention.

FIG. 2 is a partial cross-section drawing illustrating a P+ implant to raise the capacitance of the source region in an NMOS device in accordance with the concepts of the present invention.

FIG. 3 is a schematic diagram illustrating a CMOS inverter that utilizes the concepts of the present invention.

### DETAILED PRESCRIPTION OF THE INVENTION

Dynamic IR drop in a power supply gives rise to numerous performance issues in integrated circuit operation. Often, a guard band must be included in the circuit design to assist in addressing these issues.

The present invention introduces an additional implant step into the integrated circuit fabrication process to improve dynamic IR drop performance. More specifically, preferably during source-drain implant processing, an additional implant mask is utilized to introduce dopant into the source regions that are connected either to V_{cc} (PMOS) or ground (NMOS) netlists.

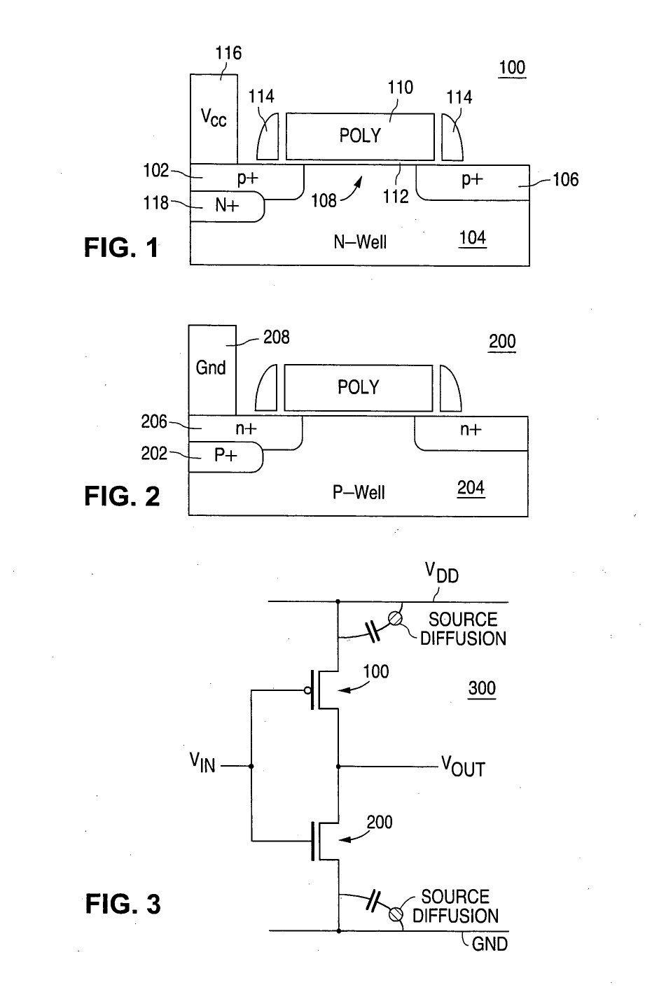

FIG. 1 shows the application of this concept to a PMOS device structure 100. The PMOS device structure 100 includes a source region 102 of P-type conductivity that is formed in a well 104 of N-type conductivity semiconductor material, typically crystalline silicon. A drain region 106, also of P-type conductivity, is formed in the N-well 104. The source region 102 and the drain region 106 are space-apart from one another to define a P-type channel region 108 therebetween. A conductive gate electrode 110, typically formed of polycrystalline silicon, is formed over the channel region 108 and is separated therefrom by intervening gate dielectric material 112, e.g. silicon dioxide. The FIG. 1 PMOS device structure 100 also includes dielectric gate sidewall spacers 114. A V_{cc} connection 116 to the source region 102 is also shown. In accordance with the concepts of the present invention, a region 118 of N-type conductivity is formed at the lower interface between the P-type source region 102 and the N-well 104.

FIG. 1 shows that the conductivity type of the N-type implant region 118 is the same as that of the underlying N-well 104. Inclusion of the extra N-type implant into the PMOS device structure 102 raises the underlying capacitance of the source region 102. This, in turn, provides for an increase in charge storage which, in turn, provides for a better level of protection against dynamic IR drop. Thus, the potential at the source (V_{cc}) node is better preserved.

FIG. 1 shows the use of an N-type implant for the source (V_{cc}) side of the device structure 100 only. In this case, an N+ implant is used to locally raise the dopant concentration under the P+ source diffusion connected to power supply V_{cc}.

Those skilled in the art will appreciate that the PMOS device structure 100, including the N-type implant region 118 can be fabricated utilizing well-known, conventional integrated circuit manufacturing process steps. Those skilled in the art will also appreciate that the N-type region 118 can be formed at various points within the fabrication of the overall device structure 100. For example, the source region 102 and the drain region 106 could be formed first using a source/drain implant mask or in a self-aligned implant step; an additional implant mask would then be formed to expose only that portion of the source region 102 to receive the N-type implant. The dopant concentration and implant energy used to introduce the N-type dopant into the interface region between the source region 102 and the N-well 104 would be selected to provide desired device characteristics given the conductivity levels of the source region 102 and the N-well 104 and the desired overall performance characteristics of the PMOS device 100.

While those skilled in the art will appreciate that the relative dopant concentrations of the source region 102, the N-well 104 and the N-type implant region 118 will depend upon a particular application, these dopant concentrations will typically be in the following range: source region 102=1e18 to 1e22; N-well 104=1e15 to 1e18; N-type implant region 118=1e17 to 1e19.

FIG. 2 shows an embodiment of the invention in which a P+ implant region 202 is used in an NMOS device structure 200 to raise the concentration of the P-well 204 directly under the N+ diffusion region 206 connected to the G_{nd} supply 208.

As with the PMOS device structure 100 described above, fabrication processes and design parameters for making the NMOS device structure 200 are well known to those skilled in the art. Typical dopant concentrations for source region 206, P-well region 204 and P-type implant region 202 will be in the following range: source region 206=1 e18 to 1e22; P-well 204=1e15 to 1e18; P-type implant region 202=1e17 to 1e19.

FIG. 3 shows a CMOS inverter 300 that utilizes a PMOS device structure 100 in accordance with the invention and an NMOS device structure 200 in accordance with the invention. The gates of both devices 100 and 200 are commonly connected to receive an input signal Vᵢₙ. The drain electrodes of both devices 100 and 200 are commonly connected to provide an output signal Vₒᵤₜ.

The issue of dynamic IR drop, which leads to ground bounce, latchup, timing errors, clock skew problems, among others, is associated with the inability of a power supply to maintain it's local voltage under demanding conditions of a switching gate that is continuously drawing power from a single power metal line. If the supply of current cannot meet the demand of the switching gate, then the voltage on the power line will drop and the performance of the switching gate will be degraded in the time domain; that is, the gate will not switch as fast as it was intended. This timing issue will lead to global timing errors such that the circuit will no longer function at speed.

The additional implant provided in accordance with the present invention raises the capacitance of the source junction, which in turn acts to provide a local source of charge, in turn behaving as a local reservoir of charge to support the demands of the switching gate. Thus, if the gate switches, it will first draw charge from this local capacitance storing charge before “refilling” from the power supply. Thus, the distributed capacitor acts to spread the power load more effectively over a “sea” of gates.

It should be understood that various alternatives to the embodiments of the invention described herein may be employed in practicing the invention. It is intended that the following claims define the scope of the invention and that structures and methods within the scope of these claims and their equivalents be covered thereby.

What is claimed is:

1. A method of forming a PMOS transistor structure in N-type semiconductor material, the method comprising:
forming space-apart P-type source and drain regions in the N-type semiconductor material to define a lower interface between the P-type source region and the N-type semiconductor material and to define an N-type channel region between the source and drain regions;
forming an N-type region at the lower interface between the P-type source region and the N-type semiconductor material; and
forming a conductive gate electrode over the N-type channel region and separated therefrom by intervening dielectric material.

2. A method of forming an NMOS transistor structure in P-type semiconductor material, the method comprising:
forming spaced-apart N-type source and drain regions in the P-type semiconductor material to define a lower interface between the N-type source region and the P-type semiconductor material and to define a P-type channel region between the source and drain regions;
forming a P-type region at the lower interface between the N-type source region and the P-type semiconductor material; and
forming a conductive gate electrode over the P-type channel region and separated therefrom by intervening dielectric material.

3. A method of forming an MOS transistor structure in semiconductor material having a first conductivity type, the method comprising:
forming a source region having a second conductivity type that is opposite the first conductivity type in the semiconductor material to define a lower interface between the source region and the semiconductor material;
forming a drain region having the second conductivity type in the semiconductor material and spaced-apart from the source region to define a channel region having the first conductivity type therebetween;
forming a conductive gate electrode over the channel region and separated therefrom by intervening dielectric material;
selectively implanting dopant atoms of the first conductivity type to form an implant region of the first conductivity type at the lower interface between the source region and the semiconductor material such that the implant region has a higher dopant concentration than the dopant concentration of the semiconductor material, thereby increasing the capacitance of the source region.

4. A method as in claim 5, and further comprising:
prior to the implanting step, forming sidewall spacers on the conductive gate electrode such that the implanting step utilizes the sidewall spacers as a mask to facilitate a self-aligned implanting step to form the implant region.

5. A method as in claim 5, and wherein:
the dopant concentration of the source region is 1e18 to 1e22;
the dopant concentration of the semiconductor material is 1e15 to 1e18; and
the dopant concentration of the implant region is 1e17 to 1e19.
